(19) United States
(12) Patent Application Publication
(10) Pub. No.: US 2019/0157218 A1
(43) Pub. Date: May 23, 2019

(54) INTERPOSER AND METHOD FOR PRODUCING HOLES IN AN INTERPOSER

(71) Applicant: Schott AG, Mainz (DE)

(72) Inventor: Oliver JACKL, Alfeld (DE)

(73) Assignee: Schott AG, Mainz (DE)

(21) Appl. No.: 16/256,093

(22) Filed: Jan. 24, 2019

Related U.S. Application Data
(63) Continuation-in-part of application No. 13/807,386, filed on Apr. 8, 2013.

(30) Foreign Application Priority Data
Jul. 2, 2010 (DE) 10 2010 025 966.7

(51) Int. Cl. H01L 23/00; H01L 23/15; H01L 23/498; H01L 21/48

(52) U.S. Cl. CPC H01L 23/562; H01L 23/15; H01L 21/486; H01L 23/49838; H01L 23/49827

(57) ABSTRACT

An interposer for electrical connection between a CPU chip and a circuit board is provided. The interposer includes a plate-shaped base substrate made of glass with a number of holes ranging from 10 to 10.000 cm⁻². Conductive paths run on one surface of the board, extend into respective holes, and extend through the holes to the other surface of the plate in order to form connection points for the chip. The holes are produced in two steps: first filamentary channels are prepared, and second the filamentary channels are widened by etching so as to get typical roughness as from etching.

### CROSS REFERENCE TO RELATED APPLICATIONS

This application is a continuation of application Ser. No. 13/807,386 filed Apr. 8, 2013, which is US National Stage application under 35 USC § 371 of PCT/EP2011/003300 filed Jul. 4, 2011, which claims benefit under 35 USC § 119(a) of German Application No. 10 2010 025 966.7 filed Jul. 2, 2010, the entire contents of all of which are incorporated herein by reference.

### BACKGROUND

### 1. Field of the Invention

The invention relates to interposers for electrically connecting the terminals of a CPU chip and a circuit board, and further relates to methods used in a critical manufacturing step of interposers.

### 2. Description of Related Art

A CPU chip, as a processor core, typically has several hundred contact points on its bottom surface, which are closely spaced to one another and distributed over a relatively small area. Due to this close spacing, these contact points cannot be mounted directly to a circuit board, the so called motherboard. Therefore, an intermediate part is employed which permits to enlarge the connection base. As an intermediate part, often, a glass fiber mat encased in epoxy material is employed, which is provided with a number of holes. Conductive paths running on one surface of the glass fiber mat extend into respective holes to fill them and to lead to the terminals of the processor core at the other surface of the glass fiber mat. For this purpose, an underfill is applied both around the processor core and between the processor core and the glass fiber mat, which protects the wires and mechanically joins the processor core and the glass fiber mat. However, the processor core and the glass fiber mat exhibit different thermal expansions. For example, the glass fiber mat has an expansion coefficient from 15 to 17×10⁻⁶/K, while the silicon-based core processor has a thermal expansion factor from 3.2 to 3.3×10⁻⁶/K. Therefore, in case of heating there are differential expansions between the core processor and the glass fiber mat and hence mechanical stresses arise between these two components. This can be detrimental to the contact connections, especially when the two components are not completely joined face to face. In this case the contact points may break easily.

Another drawback of using a glass fiber mat is related to the mechanical drilling of holes into the glass fiber mat. The hole diameter is limited to 250 to 450 μm.

Another possibility of designing and manufacturing connecting structures which could be used as a type of interposer is described in WO 02/058135 A2. Wafer technology is employed, including the generation of holes and trenches in dielectric material, such as silicon dioxide, and filling of the holes and trenches with conductive layers. However, this method of producing contact connections is very expensive.

A similar technology is taught in DE 103 01 291 B3. Recesses are etched into substrates and filled with metal conductive paths, and contacts extending through holes are also provided. This technique is complex and expensive.

U.S. 2002/0180015 A1 discloses a multi-chip module which includes semiconductor devices and a wiring substrate for mounting the semiconductor devices. The wiring substrate comprises a glass substrate having holes which were formed by a sand blasting treatment. A wiring layer is formed on the surface of the glass substrate. Furthermore, the glass substrate has wirings and an insulation layer. It is aimed at selecting the coefficient of thermal expansion of the glass substrate close to the coefficient of silicon.

U.S. Pat. No. 5,216,207 discloses ceramic multilayer circuit boards including silver conductors. The layers are fired at low temperatures. The circuit boards have a coefficient of thermal expansion close to that of silicon.

U.S. 2009/0321114 A1 discloses an electrical testing substrate unit including a multilayer ceramic substrate. Although the materials used have a coefficient of thermal expansion close to the value of the invention, they are not pure glasses.

U.S. Pat. No. 7,550,321 B1 discloses a substrate having a coefficient of thermal expansion with a gradient in the thickness direction.

The paper “Femtosecond laser-assisted three-dimensional microfabrication in silica” in Optics Letters, Vol. 26, No. 5, Mar. 1, 2001, pages 277-279 describes direct three-dimensional microfabrication in a silicate glass. The fabrication process is accomplished in two steps. First, the intended patterns are mapped out in the glass using focused femtosecond laser pulses. Then these patterns are etched.

### SUMMARY

An object of the invention is to provide an interposer for electrical connection between a CPU chip and a circuit board, which is economical to produce and enables to produce microholes with a hole diameter in the order of 20 μm and 200 μm, and wherein the interposer body exhibits a thermal expansion similar to that of the CPU chip material.

The novel interposer should be able to meet the following requirements: Multiple small holes (10 to 10,000) are to be accommodated in each interposer, with close tolerances of the holes to each other. It has to be possible to ensure a hole spacing down to 30 μm. Hole diameters down to a size of 20 μm should be possible. A ratio of the thickness of the interposer to the hole diameter, the so-called aspect ratio, from 1 to 10 should be possible. A center-to-center distance of the holes in a range from 120 μm and 400 μm should be possible. The hole should have a conical or crater-shaped inlet and outlet to the hole, but the inner walls of the hole in the center should be of cylindrical shape. The hole should have smooth walls (fire-polished). Optionally, a bead may be produced around the edge of the hole, having a height of not more than 5 mm.

The interposer according to the invention is characterized in that its board-shaped base substrate is made of glass having a coefficient of thermal expansion ranging from 3.1×10⁻⁶/K to 3.4×10⁻⁶/K. Silicon-based chip boards exhibit an expansion coefficient between 3.2×10⁻⁶/K and 3.3×10⁻⁶/K. Therefore, large mechanical stresses between the interposer and the CPU chip due to different thermal expansion behavior are not to be expected.

The number of holes in the interposer is selected according to the particular requirements and may amount up to 10,000 holes per cm². A usual number of holes ranges from 1000 to 3000. The center-to-center spacing of the holes ranges from 50 μm to 700 μm. To meet the requirements of miniaturization of components, holes are provided which have a diameter ranging from 20 μm to 200 μm. To establish an electrical connection between the CPU chip and its circuit board, conductive paths extend on one of the surfaces of the interposer board to and into the holes and therethrough to form connection points for the CPU chip.

The glass of the base substrate should have an alkali content of less than 700 ppm. Such a glass has a low coefficient of thermal expansion, as required, and exhibits very good signal-insulating properties, due to the high dielectric value. Furthermore, the risk of contamination of silicon processors with alkalis is largely avoided.

For reasons of environmental protection, an arsenic or antimony content of the glass composition is less than 50 ppm.

Interposer boards have a thickness of less than 1 mm, but not below 30 μm. The number of holes of an interposer is chosen according to the needs, and is in the order from 1000 to 3000 holes per cm². The invention targets to offer interposers on the market having microholes smaller than 100 μm. Hence, the holes are closely packed, with a center-to-center distance of the holes that may range from 150 μm to 400 μm. However, the edge-to-edge distance of the holes should not be less than 30 μm. The holes need not all have the same diameter, it is possible that holes of different diameters are provided in the board-shaped base substrate. The ratio of the thickness of the glass board to the hole diameter, the so-called aspect ratio, may be selected in a wide range from 0.1 to 25, an aspect ratio from 1 to 10 being preferred. The holes generally have a thin cylindrical shape, but may have rounded-broken edges at the inlet and outlet of the hole.

In order to accurately position the holes, which may have a diameter ranging from 20 μm to 200 μm, focused laser pulses are used in a wavelength range of transparency of the glass, so that the laser beams penetrate into the glass and are not already absorbed in the surface layers of the glass. The laser radiation used has a very high radiation intensity, so as to result in local non-thermal destruction of the glass along filamentary channels. These filamentary channels are subsequently widened to the desired diameter of the holes, for which purpose dielectric breakdowns may be employed which cause electro-thermal heating and evaporation of the material of the hole edges, and/or the filamentary channels are widened by supplying reactive gases.

It is also possible to precisely mark the intended perforation points using RF coupling material which is printed onto the base substrate in form of dots. Such marked points are heated by RF energy to lower the breakdown strength to electrical high voltage in the region of the intended holes, and to finally cause dielectric breakdowns at these points. The perforations may be widened by supplied etching gas.

The manufacturing of the conductive paths on the board-shaped glass substrate and through the holes is accomplished by known method patterns and need not be further described here.

### BRIEF DESCRIPTION OF THE DRAWINGS

Exemplary embodiments of the invention will be described with reference to the drawings, wherein:

FIG. 1 schematically illustrates, in a longitudinal sectional view, one way of producing an interposer,

FIG. 2 illustrates a second way of producing an interposer, and

FIG. 3 an interposer, schematically.

### DETAILED DESCRIPTION

In a first method step, perforation points 10 on a board-shaped glass substrate 1 are marked by focused laser pulses 41 emanating from an array 4 of lasers 40. The radiation intensity of these lasers is so strong that it causes local non-thermal destruction in the glass along a filamentary channel 11.

In a second method step, filamentary channels 11 are widened into holes 12. For this purpose, opposing electrodes 6 and 7 may be employed, to which high voltage energy is applied, resulting in dielectric breakdowns across the glass substrate along filamentary channels 11. These breakthroughs are widened by electro-thermal heating and evaporation of the perforation material until the process is stopped by switching off the power supply when the desired hole diameter is achieved.

Alternatively or additionally, the filamentary channels 11 may be widened using reactive gases, as illustrated by nozzles 20, 30, which direct the gas to the perforation points 10.

In the next method step, conductive paths 13 to the perforation points 10 are applied on the upper surface of glass board 1, and the holes 12 are filled with conductive material 14 to complete the connections to the contact points of a CPU chip or the like at the bottom surface of the board. (For mounting on the motherboard, glass board 1 is turned around.)

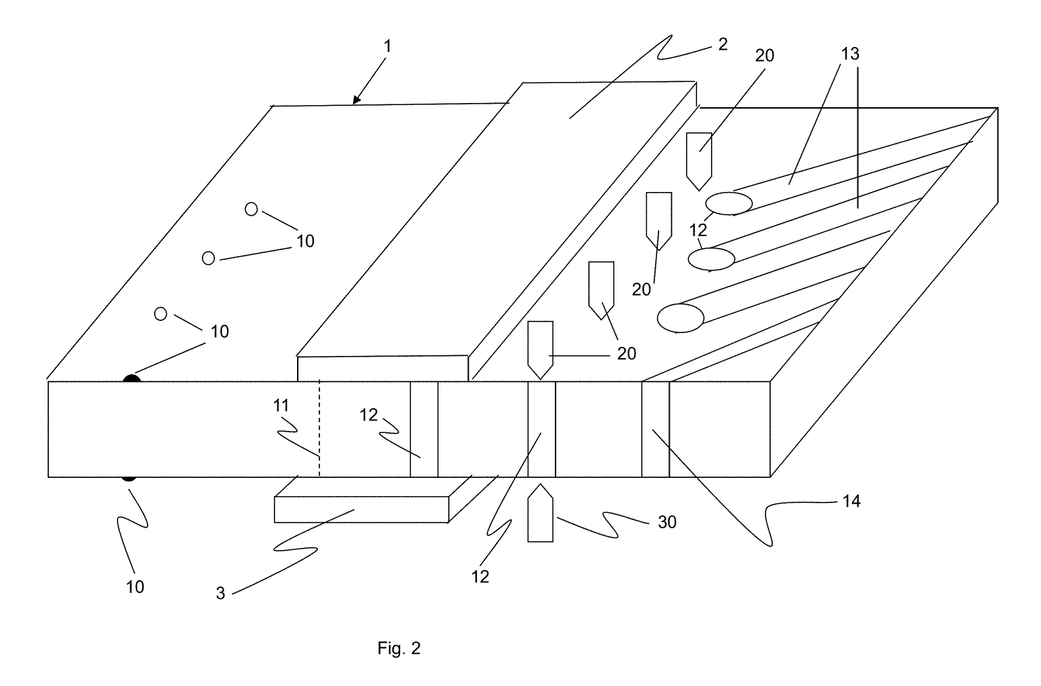

FIG. 2 shows another way of producing microholes. Perforation points 10 are marked by precisely imprinted RF coupling material. At these points 10 high frequency energy is applied by means of electrodes 2, 3, so that the coupling points themselves and the glass material between the upper surface coupling points and the lower surface coupling points is heated, causing the dielectric strength of the material to be lowered. When a high voltage is applied, dielectric breakdowns will occur along narrow channels 11. By continuing the supply of high-voltage energy, these narrow channels 11 may be widened to the size of holes 12.

However, it is also possible, for widening the narrow channels 11 resulting from dielectric breakdowns, to use reactive gas which is supplied through nozzles 20, 30.

Finally, conductive paths 13 to the holes 12 are applied on the upper surface of the glass substrate, and the holes are filled with conductive material 14 in order to establish the connections for the CPU chip, with the glass board 1 turned around.

It should be noted that interposers need not to be produced separately, rather glass substrate boards for a plurality of interposers may be processed, and the large-sized glass substrate boards may be cut to obtain the individual interposers. Glass substrate boards of a size with edge lengths of 0.2 m by 3 m (or less) can be processed. Round board formats may have dimensions of up to 1 m.

Glasses were melted at 1620° C. in Pt/Ir crucibles from conventional, essentially alkali-free raw materials, apart from unavoidable impurities. The melt was refined for one and a half hour at this temperature, then poured into inductively heated platinum crucibles and stirred for 30 minutes at 1550° C. for homogenization.

The table shows fifteen examples of suitable glasses and their compositions (in wt. % based on oxide) and their main features. The refining agents SnO₂ (Examples 1-8, 11, 12, 14, 15) and As_{Z}O₃(Examples 9, 10, 13) with a proportion of 0.3 wt. % is not listed. The following properties are specified:

the coefficient of thermal expansion α_{20/300} (10⁻⁶/K)

the density [symbol] (g/cm³)

the dilatometric glass transition temperature T_{g} (° C.) according to DIN 52324

the temperature at a viscosity of 10⁴ dPa·s (referred to as T4 [° C.])

the temperature at a viscosity of 10² dPa·s (referred to as T2 [° C.]), calculated from the Vogel-Fulcher-Tammann equation

an “HCl” acid resistance as weight loss (material removal value) of glass boards measuring 50 mm×50 mm×2 mm and polished on all sides after treatment with 5% hydrochloric acid for 24 hours at 95° C. (mg/cm²).

a “BHF” resistance to buffered hydrofluoric acid as a weight loss (material removal value) of glass boards measuring 50 mm×50 mm×2 mm and polished on all sides after treatment with 10% NH₄F NH₄F.HF for 20 min at 23° C. (mg/cm²)

the refractive index n_{d}.

### Examples

Compositions (in wt. % based on oxide), and essential properties of glasses according to the invention

| | 1 | 2 | 3 | 4 | 5 | 6 |
|---|---|---|---|---|---|---|
| SiO₂ | 60.0 | 60.0 | 59.9 | 58.9 | 59.9 | 61.0 |
| B₂O₃ | 7.5 | 7.5 | 7.5 | 8.5 | 7.5 | 9.5 |
| Al₂O₃ | 21.5 | 21.5 | 21.5 | 21.5 | 21.5 | 18.4 |
| MgO | 2.9 | 2.9 | 2.0 | 2.0 | 2.9 | 2.2 |
| CaO | 3.8 | 2.8 | 3.8 | 3.8 | 4.8 | 4.1 |
| BaO | 4.0 | 5.0 | 5.0 | 5.0 | 3.1 | 4.5 |
| ZnO | — | — | — | — | — | — |
| α_{20/300} (10⁻⁶/K) | 3.07 | 3.00 | 3.01 | 3.08 | 3.13 | 3.11 |
| [symbol] (g/cm³) | 2.48 | 2.48 | 2.48 | 2.48 | 2.47 | 2.45 |
| Tg (° C.) | 747 | 748 | 752 | 741 | 743 | 729 |
| T 4 (° C.) | 1312 | 1318 | 1315 | 1308 | 1292 | 1313 |
| T 2 (° C.) | 1672 | 1678 | 1691 | 1668 | 1662 | 1700 |
| n_{d} | 1.520 | 1.518 | 1.519 | 1.519 | 1.521 | 1.515 |
| HCl (mg/cm²) | 1.05 | n.m. | 0.85 | n.m. | 1.1 | n.m. |
| BHF (mg/cm²) | 0.57 | 0.58 | 0.55 | 0.55 | 0.56 | 0.49 |
| | 7 | 8 | 9 | 10 | 11 | 12 |
| SiO₂ | 58.5 | 62.8 | 63.5 | 63.5 | 59.7 | 59.0 |
| B₂O₃ | 7.7 | 8.2 | 10.0 | 10.0 | 10.0 | 9.0 |
| Al₂O₃ | 22.7 | 16.5 | 15.4 | 15.4 | 18.5 | 17.2 |
| MgO | 2.8 | 0.5 | 2.0 | 1.0 | | 2.0 |
| CaO | 2.0 | 4.2 | 5.6 | 6.6 | 8.3 | 9.0 |
| BaO | 5.0 | 7.5 | 3.2 | 3.2 | 3.2 | 3.5 |
| ZnO | 1.0 | — | — | — | — | — |
| α_{20/300} (10⁻⁶/K) | 2.89 | 3.19 | 3.24 | 3.34 | 3.44 | 3.76 |
| [symbol] (g/cm³) | 2.50 | 2.49 | 2.42 | 2.43 | 2.46 | 2.50 |
| Tg (° C.) | 748 | 725 | 711 | 719 | 714 | 711 |
| T 4 (° C.) | 1314 | 1325 | 1320 | 1327 | 1281 | 1257 |
| T 2 (° C.) | 1674 | 1699 | n.m. | n.m. | 1650 | 1615 |
| n_{d} | 1.520 | 1.513 | 1.511 | 1.512 | 1.520 | 1.526 |
| HCl (mg/cm²) | n.m. | 0.30 | 0.89 | n.m. | n.m. | 0.72 |
| BHF (mg/cm²) | 0.62 | 0.45 | 0.43 | 0.40 | 0.44 | 0.49 |

| | 13 | 14 | 15 |
|---|---|---|---|
| SiO₂ | 61.4 | 59.5 | 63.9 |
| B₂O₃ | 8.2 | 10.0 | 10.4 |
| Al₂O₃ | 16.0 | 16.7 | 14.6 |
| MgO | 2.8 | 0.7 | 2.9 |
| CaO | 7.9 | 8.5 | 4.8 |
| BaO | 3.4 | 3.8 | 3.1 |
| ZnO | — | 0.5 | — |
| α20/300 (10⁻⁶/K) | 3.75 | 3.60 | 3.21 |
| [symbol] (g/cm³) | 2.48 | 2.48 | 2.41 |
| Tg (° C.) | 709 | 702 | 701 |
| T 4 (° C.) | 1273 | 1260 | 1311 |
| T 2 (° C.) | 1629 | 1629 | n.m. |
| n_{d} | 1.523 | 1.522 | n.m. |
| HCl (mg/cm²) | 0.41 | 0.97 | n.m. |
| BHF (mg/cm²) | 0.74 | 0.47 | n.m. |

n.m. = not measured

As the exemplary embodiments illustrate, the glasses have the following advantageous properties:

a thermal expansion α_{20/300} of between 2.8×10⁻⁶/K and 3.8×10⁻⁶/K, in preferred embodiments ≤3.6×10⁻⁶/K, in particularly preferred embodiments <3.2×10⁻⁶/K, and thus matched to the expansion behavior of both amorphous silicon and also increasingly polycrystalline silicon.

with T_{g}>700° C., a high glass transition temperature, i.e. a high temperature resistance. This is essential for a lowest possible production-related shrinkage (“compaction”) and for use of the glasses as substrates for coatings of amorphous Si layers and subsequent annealing thereof.

with [symbol] <2.600 g/cm³, a low density

a temperature at a viscosity of 10⁴ dPa·s (working point V_{A}) of not more than 1350° C., and a temperature at a viscosity of 10² dPa·s of not more than 1720° C., which is a suitable viscosity characteristic in terms of hot-shaping and meltability.

with n_{d}≤1.526 a low refractive index.

a high chemical resistance, as is evident inter alia from good resistance to buffered hydrofluoric acid solution.

The glasses exhibit high thermal shock resistance and good devitrification stability. The glasses can be produced as flat glasses by various drawing methods, e.g. microsheet down-draw, up-draw, or overflow fusion methods, and, in a preferred embodiment, if they are free of As₂O₃ and Sb₂O₃, also by the float process.

With these properties, the glasses are highly suitable for use as substrate glass for producing interposers.

By using the base substrate of low-alkali glass and with a coefficient of thermal expansion very close to that of the chip of silicon material, difficulties resulting from different thermal expansions of the interposer and the CPU chip are largely avoided. If adjacent joint material layers or boards have an only slightly different heating behavior and a slightly different coefficient of thermal expansion, there will be fewer mechanical stresses between these joint layers or boards, and there will be no warpage or cracking between the layers or boards.

Interposers which are occupied more densely with holes as compared to previous interposers, take smaller substrate sizes, thereby still further reducing the amount of different expansions and contractions of the involved layers or boards and thus the risk of warpage and hence cracking between the involved layers or boards.

Finally, cost savings can also be expected because (with reduced interposer size and hole size) less glass material and less conductive material for filling the holes has to be used.

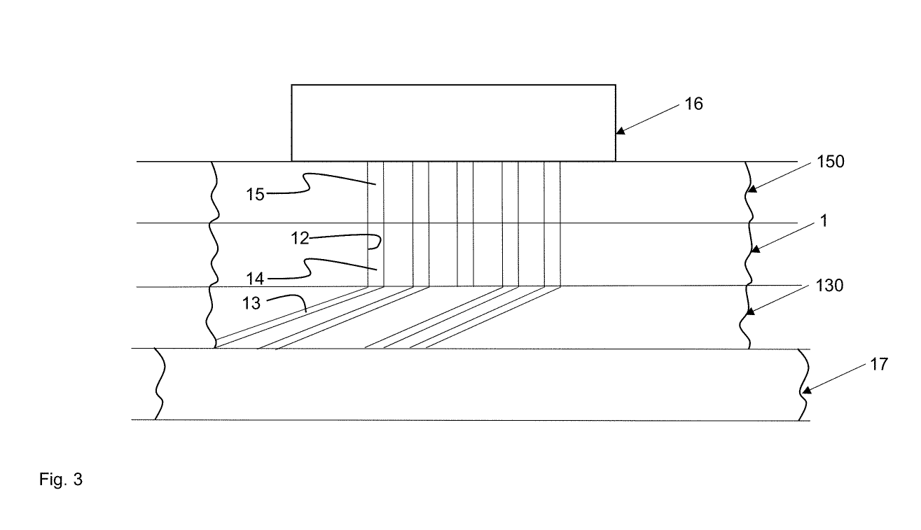

In addition to the preceding description, a sectional view of an interposer is shown schematically in FIG. 3.

The interposer is mounted on a circuit board 17 and carries a CPU chip 16. Contact points 15 of the CPU chip 16 schematically are shown in a first lead distribution layer 150, and the conductive paths 13 are indicated in a second lead distribution layer 130. The board-shaped base substrate 1 forms a glass plate. Etching can be accomplished by reactive gases or by wet etching.

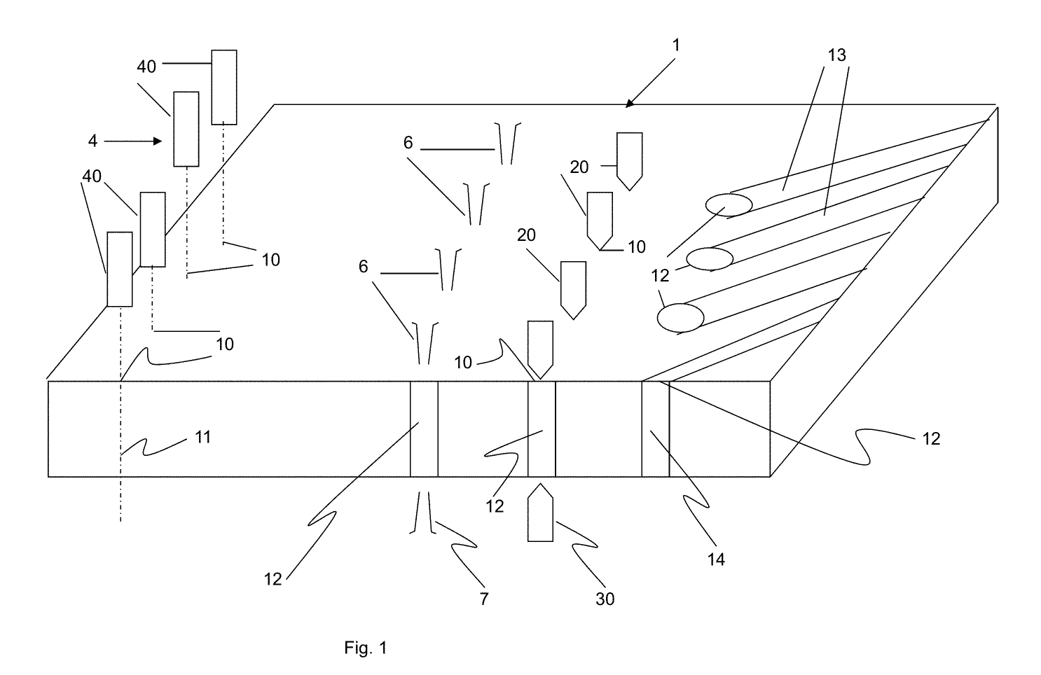

Referring to FIGS. 1 and 2, in the preferred method of producing holes in such interposer, the board-shaped base substrate 1 made of a single layer of glass is exposed to focused laser pulses at predetermined perforation points 10 with a radiation intensity that causes each a local non-thermal destruction of the glass along a filamentary channel 11, and the filamentary channels 11 are widened by etching to the desired diameter of the holes 12 which get a generally cylindrical shape with inner cylindrical walls having typical roughness as from etching. The edges between the inner cylindrical walls of the holes and the outer substrate surfaces are rounded and form transition zones that make it easier to fill into the holes conductive material that bonds with the hole roughnesses.

It has been found that the base substrate 1 made of a single layer of glass can have a thickness in the range between 10 μm and 3 mm. The holes 12 in the substrate can have diameters that range from 1 μm to 1 mm. The holes can have a small distance form on another, or adjacent holes can even merge so that bigger holes are cut out using holes arranged along a circle, or webs are formed with remaining base substrate material so as to form a web structure.

It is well known that glass is very robust and rigid as a material, therefore, even very thin glass plates can be used in interposers, compared to plastics. Thicknesses of 20 μm, 30 μm, 40 μm, 50 μm, 60 μm, 70 μm, 80 μm, 90 μm and 100 μm are envisaged as substrates for interposers of reduced size. But also substrates in interposers for heavy duty applications can be made in thicknesses of 0.7 mm, 1.0 mm, 2.0 mm, 2.8 mm and 3.0 mm. For medium duty applications, substrates of 0.2 mm, 0.3 mm, 0.4 mm, 0.5 mm and 0.6 mm can be used.

Further examples No. 16 to 25 for glass compositions in wt % useful as a substrate for producing interposers are mentioned subsequently.

| | 16 | 17 | 18 | 19 | 20 | 21 | 22 | 23 | 24 | 25 |
|---|---|---|---|---|---|---|---|---|---|---|
| SiO₂ | 61 | 64.0 | 69 ± 5 | 80 ± 5 | 60.5-61.5 | 78.575 | 71.660 | 80.437 | 73.884 | 78.909 |
| B₂O₃ | 10 | 8.3 | | 13 ± 5 | | 0.200 | 0.750 | | | |
| Al₂O₃ | 18 | 4.0 | | 2.5 ± 2 | 16.8-17 | 4.243 | 6.000 | 4.828 | 7.161 | 4.301 |
| MgO | 2.8 | | | | 3.9-4.04 | | | | | |
| CaO | 4.3 | | 7 ± 2 | | | | | | | |
| BaO | 3.3 | | 2 ± 2 | | | | | | | |
| Na₂O | | 6.5 | 8 ± 2 | 3.5 ± 2 | 12.1-12.3 | 1.711 | 2.000 | | 2.725 | 1.700 |
| K₂O | | 7.0 | 8 ± 2 | 1 ± 1 | 4.0-4.1 | 3.963 | 6.000 | 3.576 | 4.137 | 4.201 |
| ZnO | | 5.5 | 4 ± 2 | | | 1.001 | 2.000 | 0.491 | | 0.960 |
| TiO₂ | | 4.0 | 1 ± 1 | | | | | | | |
| Sb₂O₃ | | 0.6 | | | | 0.550 | 0.400 | 0.230 | 0.398 | 0.400 |
| ZrO₂ | | | | | 1-1.56 | | | | | |
| SnO₂ | | | | | 0.07-0.3 | | | | | |
| CeO₂ | | | | | 0.3-0.09 | 0.040 | 0.040 | 0.010 | 0.030 | 0.018 |
| Fe₂O₃ | | | | | 0.01-0.012 | | | | | |
| F | | | | | 0.07-0.15 | | | | | |
| SO₃ | | | | | 0.017-0.013 | | | | | |
| Cl | | 0.1 | | | 0.011-0.006 | | | | | |
| Li₂O | | | | | | 9.557 | 11.000 | 10.418 | 11.546 | 9.401 |
| Ag₂O | | | | | | 0.160 | 0.150 | 0.010 | 0.119 | 0.110 |

As a basic material for the glass plate that can be used as a substrate for producing interposers, also photosensitive glasses can be used. In such a case, preparatory steps are preferably applied before the substrate is exposed to focused laser pulses so as to produce the filamentary channels 11. The preparatory steps consists in exposing to ultra violet radiation the glass about the predetermined perforation points 10 with the desired diameters of the holes 12, and in tempering the glass. Thereafter, strong focused laser pulses are directed at the predetermined perforation points 10 which make the substrate brittle along the filamentary channels 11. Thus, the filamentary channels offer a path wherein etching means can enter quickly and deeply. This favors forming of well defined inner cylindrical walls of the holes 12. Wet etching can be used also from both sides of the substrate to widen the filamentary channels 11 to the desired diameters of the holes 12, where double conus shape of the holes is avoided. A preferred etching solution includes KOH highly concentrated, and HF. Concentration: 6 mol/L KOH; HF 3-10. wt % Etching parameter: KOH at 100° C. for 4 hours; HF at room temperature for 2 hours.

After widening of the holes 12 in the glass plate, the glass plate as such can be used as a component in an interposer, or the glass plate is ceramized to get a glass-ceramic plate useful in making an interposer

What is claimed is:

1. An interposer assembly, comprising:
a CPU chip;
a circuit board;
a board-shaped base substrate made of glass forming a first interposer surface and a second interposer surface, the base substrate having a coefficient of thermal expansion ranging from 2.8×10⁻⁶/K to 3.8×10⁻⁶/K, the base substrate having a number of holes transversely to the first and second interposer surfaces, the number of holes ranging from 10 to 10,000, the holes comprising diameters ranging from 20 μm to 200 μm, and the holes comprising a center-to-center distance in a range from 50 μm to 700 μm; and
conductive paths running on the first interposer surface, extending into the holes, and extending through the holes to the second interposer surface to form connection points for the CPU chip,
wherein the CPU chip and the circuit board are directly connected to the first and second interposer surfaces.

2. The interposer assembly of claim 1, wherein the glass of the base substrate has an alkali content of less than 700 ppm.

3. The interposer assembly of claim 1, wherein the glass of the base substrate has an arsenic or antimony content of less than 50 ppm.

4. The interposer assembly of claim 1, wherein the coefficient of thermal expansion is 3.2×10⁻⁶/K.

5. The interposer assembly of claim 1, wherein the base substrate has a thickness that ranges from 30 μm to 1000 μm.

6. The interposer assembly of claim 1, wherein the number of holes ranges from 1000 to 3000.

7. The interposer assembly of claim 1, wherein the diameter of the holes does not exceed 100 μm.

8. The interposer assembly of claim 1, wherein the center-to-center distance of the holes ranges from 150 μm to 400 μm.

9. The interposer assembly of claim 1, wherein the holes have an edge-to-edge distance that is at least 30 μm.

10. The interposer assembly of claim 1, wherein the base substrate has holes of different diameters.

11. The interposer of claim 10, wherein the holes of different diameters comprise: a ratio of the center-to-center distance to the diameter ranging from 1 to 10, a ratio of the edge-to-edge distance to the diameter ranging from 1 to 9, and a ratio of a board thickness of the substrate to the diameter ranging from 0.1 to 25.

12. The interposer of claim 1, wherein the holes have an edge at the first or second interposer surface that is rounded or broken.

13. An interposer assembly, comprising:
a CPU chip;
a circuit board;
a board-shaped base substrate made of a single layer of glass and forming a first interposer surface and a second interposer surface;
a number of holes extending through a thickness of the base substrate transversely to the first and second interposer surfaces, the number of holes having inner walls with cylindrical shape, the inner walls having an etched roughness, the number of holes each having a conical or crater-shaped inlet and outlet or a transition zone with rounded edges between the inner wall and the first and second interposer surfaces, respectively; and
conductive material filling the number of holes, wherein the CPU chip and the circuit board are directly connected to the first and second interposer surfaces, respectively.

14. The interposer assembly of claim 13, wherein the holes have been produced by aligning a multiple laser beam array to predetermined perforation points of the base substrate, triggering focused laser pulses in a wavelength range in which the glass is at least partially transparent and with a radiation intensity that causes each a local non-thermal destruction of the glass along a respective filamentary channel, and widening each filamentary channel to a desired diameter of the holes by etching such that the holes generally get the cylindrical shape with the rounded edges at the inlet and outlet of the hole, and with the typical roughness as from etching.

15. The interposer assembly of claim 13, wherein the conductive material forms conductive paths running on the first interposer surface and extends into the holes to the second interposer surface to form connection points for the CPU chip.

16. The interposer assembly of claim 13, wherein the holes include holes of different diameters that comprise a ratio of center-to-center distance to hole diameter ranging from 1 to 10; a ratio of inner wall-to-inner wall distance to hole diameter ranging from 1 to 9; and a ratio of interposer thickness to hole diameter ranging from 0.1 to 25.

17. A glass plate of a single layer with a number of holes extending through the plate thickness from a first plate surface to a second plate surface, the glass plate being adapted as a substrate for producing interposers, wherein the holes have been produced by preparing local non-thermal destruction of the glass along respective filamentary channels in the glass by triggering focused laser pulses in a wavelength range in which the glass is at least partially transparent, and widening the filamentary channels to the desired diameter of the holes by etching such that the holes get a cylindrical shape along its length and with inner walls having typical roughness as from etching.

18. The glass plate of claim 17, wherein the holes have transition zones to the first and second plate surfaces which show rounded edges between the inner cylindrical walls of the holes and the outer first and second plate surfaces.

19. The glass plate of claim 17 comprising a thickness in the range between 10 μm and 3 mm.

20. The glass plate of claim 17, wherein the holes have diameters ranging from 1 μm to 1 mm.

21. An interposer assembly, comprising:
a CPU chip;
a circuit board;
a board-shaped base substrate made of glass forming a first interposer surface and a second interposer surface, the base substrate having a coefficient of thermal expansion ranging from 2.8×10⁻⁶/K to 3.8×10⁻⁶/K, the base substrate, transversely to the first and second interposer surfaces, having a number of holes which, starting from respective filamentary channels through the board-shaped base substrate, are widened as a result from etching, with a cylindrical inner wall in a hole center and with a conical or crater-shaped inlet or outlet to the hole, or a transition zone with rounded edges between inner wall and first and second interposer surfaces, respectively, the holes having a roughness as a result from etching, the number of holes ranging from 10 to 10,000, the holes comprising diameters ranging from 20 μm to 200 μm, and the holes comprising a center-to-center distance in a range from 50 μm to 700 μm; and
conductive paths running on the first interposer surface, extending into the holes, and extending through the holes to the second interposer surface to form connection points for the CPU chip, wherein the CPU chip and the circuit board are directly connected to the first and second interposer surfaces.

22. An interposer assembly, comprising:
a CPU chip;
a circuit board;
a board-shaped base substrate made of a single layer of glass and forming a first interposer surface and a second interposer surface;
a number of holes extending through a thickness of the base substrate transversely to the first and second interposer surfaces, the holes having inner walls with cylindrical shape as from etching filamentary channels through the base substrate, and a transition zone with rounded edges between the inner wall and the first and second interposer surfaces, respectively, as from etching the holes having an etched roughness; and
conductive filling material filling the holes, wherein the CPU chip and the circuit board are connected to the conductive filling material on the first and second interposer surfaces, respectively.

23. A glass plate of a single layer with a number of holes extending through the plate thickness from a first plate surface to a second plate surface, the glass plate being adapted as a substrate for producing interposers, wherein the holes have been produced by preparing respective filamentary channels in the glass and widening the filamentary channels to a desired diameter of the holes by etching such that the holes get a cylindrical shape along its length and with rounded edges between the inner cylindrical walls of the holes and the outer first and second plate surfaces the hole walls having typical roughness as from etching.
